(19) United States
(12) Patent Application Publication
(10) Pub. No.: US 2025/0382215 A1
(43) Pub. Date: Dec. 18, 2025

(54) GLASS COMPOSITION, GLASS SUBSTRATE COMPRISING THE GLASS COMPOSITION, AND DISPLAY DEVICE COMPRISING THE GLASS SUBSTRATE

(71) Applicants: Samsung Display Co., Ltd., Yongin-si, (KR); KONGJU NATIONAL UNIVERSITY INDUSTRY-UNIVERSITY COOPERATION FOUNDATION, Gongju-si (KR)

(72) Inventors: Jinsu NAM, Yongin-si (KR); Woon Jin CHUNG, Gongju-si (KR); Nam-soo KANG, Yongin-si (KR); Byeong-Beom KIM, Yongin-si (KR); Seung KIM, Yongin-si (KR); Seung Ho KIM, Yongin-si (KR); Gyeong Dae PARK, Gongju-si (KR); Seong Young PARK, Gongju-si (KR); Cheol Min PARK, Yongin-si (KR); Gyu In SHIM, Yongin-si (KR); JAEGIL LEE, Yongin-si (KR); Jin Wook JANG, Gongju-si (KR); Jin-Won JANG, Yongin-si (KR)

(21) Appl. No.: 19/173,704

(22) Filed: Apr. 8, 2025

(30) Foreign Application Priority Data
Jun. 12, 2024 (KR) 10-2024-0076454

(51) Int. Cl. C03C 3/078; C03C 3/076; H05K 5/03

(52) U.S. Cl. CPC C03C 3/078; C03C 3/076; H05K 5/03

(57) ABSTRACT

A glass composition includes 55 mol % to 70 mol % of SiO₂, 0 mol % to 10 mol % of Al₂O₃, 5 mol % to 20 mol % of Na₂O, 5 mol % to 20 mol % of K₂O, and 0 mol % to 15 mol % of RO, wherein R includes at least one selected from among Pb, Mg, Ca, Ba, and Sr.

### CROSS-REFERENCE TO RELATED APPLICATION

This application claims priority to and the benefit of Korean Patent Application No. 10-2024-0076454, filed on Jun. 12, 2024, in the Korean Intellectual Property Office, the entire content of which is incorporated herein by reference.

### BACKGROUND

### 1. Field

One or more aspects of embodiments of the present disclosure relate to a glass composition, a glass substrate including the glass composition, and a display device including the glass substrate.

### 2. Description of the Related Art

Glass substrates are widely utilized in electronic devices, including display devices and building materials. For example, glass substrates are employed in display devices such as liquid crystal displays (LCDs), organic light-emitting displays (OLEDs), electrophoretic displays, cover windows, and/or the like that protect these devices (as the substrates).

With the increasing prevalence of portable electronic devices such as smartphones and/or tablet PCs, glass substrates are frequently subjected to external impacts. Therefore, the development of thin glass substrates that can withstand such impacts is desirable for enhancing portability. Recently, foldable display devices have been researched to enhance user convenience. The glass substrate used in foldable display devices should be thin to alleviate bending stress when folded, while also possessing sufficient strength to withstand external impacts.

### SUMMARY

One or more aspects of embodiments of the present disclosure are directed toward a glass composition with (having) a low Young's modulus, a glass substrate including the glass composition, and a display device including the glass substrate.

The preceding and other aspects of the present disclosure will become more apparent to one of ordinary skill in the art to which the present disclosure pertains by referencing the detailed description of the present disclosure.

A glass composition according to one or more embodiments may include about 55 mol % to about 70 mol % of SiO₂, 0 mol % to about 10 mol % of Al₂O₃, about 5 mol % to about 20 mol % of Na₂O, about 5 mol % to about 20 mol % of K₂O, and 0 mol % to about 15 mol % of RO, wherein R includes at least one selected from among (e.g., of) Pb, Mg, Ca, Ba, and Sr.

The glass composition may include about 60 mol % to about 65 mol % of SiO₂.

The glass composition may further include Li₂O.

A glass substrate according to one or more embodiments may be made from the herein-described glass composition.

A thickness of the glass substrate may be about 30 micrometer (μm) to about 60 μm.

A thermal expansion coefficient (10⁻⁷ K⁻¹) of the glass substrate may be about 90*10⁻⁷/K to about 200*10⁻⁷/K.

The thermal expansion coefficient (10⁻⁷K⁻¹) of the glass substrate may be about 130*10⁻⁷ per degree Kelvin (/K) to about 200*10⁻⁷/K.

A glass transition temperature T_{g} of the glass substrate may be about 380 degrees centigrade (° C.) to 500° C.

A density of the glass substrate may be about 2.7 gram per cubic centimeter (g/cm³) to about 3.2 g/cm³.

A Young's modulus of the glass substrate may be about 45 gigapascal (GPa) to about 70 GPa.

The Young's modulus of the glass substrate may be about 60 GPa to about 70 GPa.

The Young's modulus of the glass substrate may be about 60 GPa to about 65 GPa.

A Poisson ratio of the glass substrate may be about 0.25 to about 0.28.

A hardness of the glass substrate may be about 4.50 GPa to about 5.50 GPa.

A fracture toughness of the glass substrate may be about 0.6 megapascal·square root meter (MPa*m^{0.5}) to about 1.0 MPa*m^{0.5}.

A brittleness of the glass substrate may be about 6.0 inverse square root micrometer (μm^{-0.5}) to about 11.0 μm^{-0.5}.

A display device according to one or more embodiments may include a

display panel including a plurality of pixels, and a glass substrate arranged on the display panel, wherein the composition of the glass substrate may include about 55 mol % to about 70 mol % SiO₂, 0 mol % to about 10 mol % of Al₂O₃, about 5 mol % to about 20 mol % of Na₂O, about 5 mol % to about 20 mol % of K₂O, and 0 mol % to about 15 mol % of RO, wherein R includes at least one selected from among (e.g., of) Pb, Mg, Ca, Ba, and Sr.

A thickness of the glass substrate may be about 30 μm to about 60 μm.

A Young's modulus of the glass substrate may be about 60 GPa to about 70 GPa.

The Young's modulus of the glass substrate may be about 60 GPa to about 65 GPa.

According to one or more embodiments, an electronic device may include the display device of the present disclosure.

According to one or more embodiments, the electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (loT) device, a smartwatch, a watch phone, or a head-mounted display (HMD).

According to one or more embodiments, a glass composition with (having) a low Young's modulus, a glass substrate including the glass composition, and a display device including the glass substrate may be provided.

### BRIEF DESCRIPTION OF THE DRAWINGS

FIG. 1 is a perspective view of a display device according to one or more embodiments.

FIG. 2 is a perspective view of a display device according to one or more embodiments.

FIG. 3 is a perspective view of the display device according to one or more embodiments of FIG. 2 in a folded state.

FIG. 4 is a schematic cross-sectional view of a display device according to one or more embodiments.

FIG. 5 is a cross-sectional view of a glass substrate according to one or more embodiments.

FIG. 6 is a step-by-step (e.g., act-by-act or task-by-task) flowchart of the manufacturing process of a glass substrate according to one or more embodiments.

FIG. 7 is a schematic view schematically showing from cutting step (e.g., act or task) to step (e.g., act or task) of surface polishing after strengthening of FIG. 6.

### DETAILED DESCRIPTION

The present disclosure will be described more fully hereinafter with reference to the accompanying drawings, in which one or more embodiments of the disclosure are shown. The present disclosure may, however, be embodied in different forms and should not be construed as limited to one or more embodiments set forth herein. As those skilled in the art would realize, the described embodiments may be modified in one or more suitable different ways, all without departing from the spirit or scope of the disclosure.

To concisely describe the disclosure, parts that are irrelevant to the description may not be provided, and like reference numerals and/or reference characters refer to like or similar constituent elements throughout the specification.

Further, because sizes and thicknesses of constituent members shown in the accompanying drawings may be arbitrarily given for better understanding and ease of description, the disclosure is not limited to the illustrated sizes and thicknesses. In the drawings, the thicknesses of layers, films, panels, regions, and/or the like, are exaggerated for clarity. In the drawings, for better understanding and ease of description, the thicknesses of some layers and areas may be exaggerated.

Because the disclosure may have diverse modified embodiments, the embodiments are illustrated in the drawings and are described in the detailed description. An aspect and a characteristic of the disclosure, and a method of accomplishing these will be apparent if (e.g., when) referring to one or more embodiments described with reference to the drawings.

It should be understood that if (e.g., when) an element such as a layer, film, region, or substrate is referred to as being “connected to,” or “on” another element, it can be directly on the other element or intervening elements may also be present. In contrast, if (e.g., when) an element is referred to as being “directly on” another element, there are no intervening elements present. Further, in the specification, the word “on” or “above” refers to positioned on or below the object portion, and does not necessarily refer to that it is positioned on the upper side of the object portion based on a gravitational direction.

As used herein, the term “and/or” includes any and all combinations of one or more of the associated listed items. Expressions such as “at least one of,” “one of,” “selected from,” and “selected from among,” when preceding a list of elements, modify the entire list of elements and do not modify the individual elements of the list. For example, throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

Unless otherwise defined, all chemical names, technical and scientific terms, and terms defined in common dictionaries should be interpreted as having meanings consistent with the context of the related art, and should not be interpreted in an ideal or overly formal sense. It will be understood that although the terms “first,” “second,” and/or the like may be utilized herein to describe one or more suitable components, these components should not be limited by these terms. These terms are only utilized to distinguish one component from another. Thus, a first element could be termed a second element without departing from the teachings of the present disclosure. Similarly, a second element could be termed a first element. An expression utilized in the singular forms such as “a,” “an,” and “the” are intended to encompass the expression of the plural forms as well, unless it has a clearly different meaning in the context.

The term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

Spatially relative terms, such as “beneath,” “below,” “lower,” “above,” “upper,” “bottom,” “top,” and the like, may be used herein for ease of description to describe one element or feature's relationship to another element(s) or feature(s) as illustrated in the drawings. It will be understood that the spatially relative terms are intended to encompass different orientations of the device in use or operation in addition to the orientation depicted in the drawings. For example, if the device in the drawings is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

In this context, “consisting essentially of” indicates that any additional components will not materially affect the chemical, physical, optical or electrical properties of the semiconductor film.

In some embodiments, unless explicitly described to the contrary, the terms “comprise,” “comprises,” “comprising,” “has,” “have,” “having,” “include,” “includes,” and/or “including,” as utilized herein will be understood to imply the inclusion of stated elements but not the exclusion of any other elements.

Further, throughout the specification, the phrase “in a plan view” refers to when an object portion is viewed from above, and the phrase “in a cross-sectional view” refers to when a cross-section taken by vertically cutting an object portion is viewed from the side.

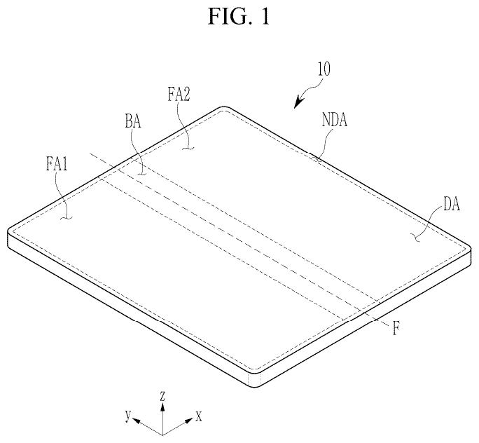

Hereinafter, a display device according to one or more embodiments will be described referring to FIG. 1.

### Display Device

FIG. 1 is a perspective view of a display device according to one or more embodiments.

In FIG. 1, a first direction x is a direction parallel to one side of a display device 10 if (e.g., when) viewed on a plane (in a plan view), and may be, for example, the horizontal direction of the display device 10. The second direction y is a direction parallel to the other side in contact with one side of the display device 10 if (e.g., when) viewed on a plane (in a plan view), and may be the vertical direction of the display device 10. A third direction z may be the thickness direction of the display device 10. When viewed on a plane (in a plan view), the display device 10 may have a rectangular shape with vertical corners or a rectangular shape with rounded corners. In a plan view, the third direction “z” is perpendicular or normal to the plane of the display device 10.

The display device 10 includes a display area DA where an image is displayed and a non-display area NDA excluding the display area.

The display area DA may be an area that displays an image including a plurality of pixels. The display area DA may be an area that displays an image including a plurality of pixels. A plurality of pixels may be arranged in a matrix pattern. The plurality of pixels may have a rectangular, diamond, or square shape if (e.g., when) viewed on a plane (in a plan view), but are not limited thereto. For example, if (e.g., when) viewed on a plane (in a plan view), the plurality of pixels may be rectangular, diamond, or other rectangles other than square, polygonal other than square, circular, or oval.

The non-display area NDA is an area that does not include pixels and may be arranged around the display area DA. The non-display area NDA may be arranged to be around (e.g., surround) the display area DA, but the present disclosure is not limited thereto. The display area DA may be partially surrounded by the non-display area NDA.

The display device 10 may be entirely unfolded flat as shown in FIG. 1. The display device 10 may include a first flat area FA1, a second flat area FA2, and a foldable area BA between the first flat area FA1 and the second flat area FA2. The foldable area BA is an area that is folded if (e.g., when) folded based on a folding axis F, and the first flat area FA1 and the second flat area FA2 are areas that are not folded. The foldable area BA may be folded around an axis parallel to the second direction y.

Although FIG. 1 shows one foldable area BA, the display device 10 according to one or more embodiments may include one or more foldable areas BA. One or more foldable areas BA may be folded around different axes, for example, an axis parallel to the first direction x and/or an axis parallel to the second direction y. In the display device 10, the position and width of the foldable area BA may be changed in one or more suitable ways.

The display device 10 may maintain both (e.g., simultaneously) the folded and unfolded states. The display device 10 may be folded using an in-folding method in which the display area DA is arranged on the inside. When the display device 10 is folded using the in-folding method, front surfaces of the display device 10 may face each other. The screen portions of the first flat area FA1 and the second flat area FA2 may be folded to face each other.

In the folded state, the screen portion of the foldable area BA may be obscured. In one or more embodiments, the display device 10 may be folded using an out-folding method in which the display area DA is arranged on the outside. When the display device 10 is folded using an out-folding method, back surfaces of the display device 10 may face each other.

In one or more embodiments, the display device 10 may be a foldable device. In this specification, a foldable device is a device that can be folded, and is used to include not only a folded device, but also a device that can have both (e.g., simultaneously) a folded state and an unfolded state. In some embodiments, folding typically includes, but is not limited to, folding at an angle of about 180°, and may also be understood as folded if (e.g., when) the folding angle exceeds 180° or does not reach 180°, for example, if (e.g., when) bent at an angle of more than 90° but less than 1 180°, or more than 120° but less than 180°. In some embodiments, the folded state may be referred to as a folded state if (e.g., when) it is in a bent state beyond the unfolded state, even if complete folding is not achieved. For example, even if it is bent at an angle of 90° or less, it can be expressed as being in a folded state to distinguish it from an unfolded state as long as the maximum folding angle is 90° or more. The radius of curvature if (e.g., when) folded may be 5 millimeter (mm) or less, e.g., in the range of 1 mm to 2 mm, or about 1.5 mm, but the present disclosure is not limited thereto.

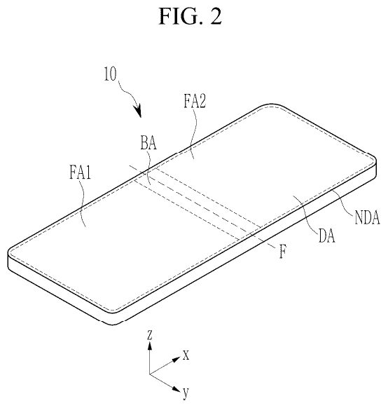

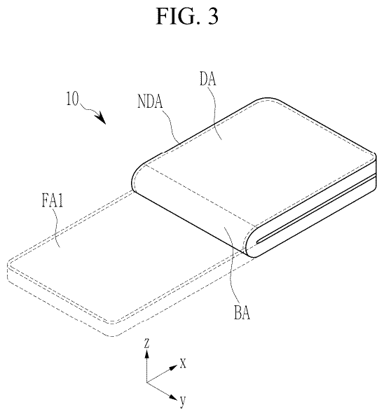

Hereinafter, a display device according to one or more embodiments will be described with reference to FIGS. 2 and 3. FIG. 2 is a perspective view of a display device according to one or more embodiments, and FIG. 3 is a perspective view of the display device according to one or more embodiments of FIG. 2 in a folded state. Descriptions of components that may each independently be the same as those described herein will not be provided.

When viewed on a plane (in a plan view), the display device 10 may include two long sides arranged in the first direction x and two short sides arranged in the second direction y. According to one or more embodiments of FIG. 2, the length of one side of the display device 10 in the first direction x may be longer than the length of the other side of the display device 10 in the second direction y. The display device 10 according to one or more embodiments may have an elongated rectangular shape along the first direction x.

In one or more embodiments, the display device 10 may be folded based on a folding axis parallel to the second direction y. Accordingly, the length of the display device 10 in the first direction x may be reduced by approximately half, which may make the display device 10 convenient for a user to carry.

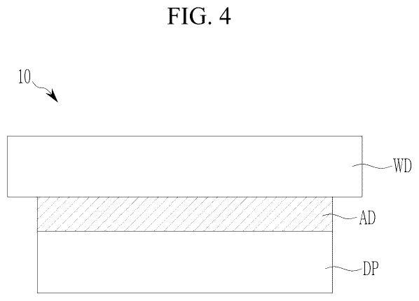

Hereinafter, a display device according to one or more embodiments will be described with reference to FIG. 4. FIG. 4 is a schematic cross-sectional view of a display device according to one or more embodiments.

Referring to FIG. 4, the display device 10 may include a display panel DP, a glass substrate WD arranged on the display panel DP and corresponding to a cover window, and an adhesive layer AD arranged on the display panel DP and the glass substrate WD to bond the display panel DP and the glass substrate WD.

The display panel DP may include a self-emission display panel, such as an organic light emitting display panel (OLED), an inorganic light emitting display panel (inorganic EL), a quantum dot light emitting display panel (QED), a micro-LED display panel (micro-LED), a nano-LED display panel (nano-LED), a plasma display panel (PDP), a field emission display panel (FED), a cathode ray display panel (CRT), as well as a light-receiving display panel, such as a liquid crystal display panel (LCD), an electrophoretic display panel (EPD), and/or the like.

The display panel DP includes a plurality of pixels and may display images using light emitted from each pixel. The display device 10 may further include a touch member.

The glass substrate WD is arranged on the display panel DP to protect the display panel DP. The glass substrate WD may be larger than the display panel DP so that the side surface thereof may protrude outward from the side surface of the display panel DP, but the glass substrate WD is not limited thereto. The display device 10 may further include a printing layer arranged on at least one surface of the glass substrate WD at an edge portion of the glass substrate WD. The printing layer prevents the bezel area of the display device 10 from being visible to the outside, and may perform a decorative function in some cases.

The adhesive layer AD may be arranged between the display panel DP and the glass substrate WD. The adhesive layer AD serves to fix the glass substrate WD on the display panel DP. The adhesive layer AD may include optically clear adhesive (OCA) or optically clear resin (OCR).

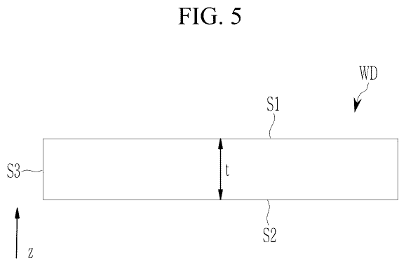

Hereinafter, the herein-described glass substrate will be described in more detail with reference to FIG. 5. FIG. 5 is a cross-sectional view of a glass substrate according to one or more embodiments. Contents that may each independently be the same as those described herein will not be provided.

Referring to FIG. 5, the glass substrate WD may include a first surface S1, a second surface S2, and a side surface S3. In the flat plate-shaped glass substrate WD, the first surface S1 and the second surface S2 are the main surfaces with a large area, and the side surface S3 is outer surface that connects the first surface S1 and the second surface S2.

The first surface S1 and the second surface S2 face each other In the thickness direction. When the glass substrate WD transmits light, the light may mainly enter one of the first surface S1 and the second surface S2 and transmit through the other.

A thickness t of the glass substrate WD is defined as the distance between the first surface S1 and the second surface S2. The thickness t of the glass substrate WD is not limited thereto, but may range from 20 micrometer (μm) to 100 μm. In one or more embodiments, the thickness t of the glass substrate WD may be 80 μm or less. In one or more embodiments, the thickness t of the glass substrate WD may be about 75 μm or less. In one or more embodiments, the thickness t of the glass substrate WD may be about 70 μm or less. In one or more embodiments, the thickness t of the glass substrate WD may be about 60 μm or less. In one or more embodiments, the thickness t of a glass product 100 may be about 65 μm or less. In one or more embodiments, the thickness t of the glass substrate WD may be about 50 μm or less. In one or more embodiments, the thickness t of the glass substrate WD may be in the range of 30 μm to 60 μm, or may have a value of around 50 μm. The glass substrate WD may have a substantially uniform thickness, but the present disclosure is not limited thereto and may have different thicknesses t for each region.

According to one or more embodiments, the glass composition forming the glass substrate WD may include SiO₂ in a content (e.g., amount) of from about 55 mol % to about 70 mol %, Al₂O₃ in a content (e.g., amount) of from 0 mol % to about 10 mol %, Na₂O in a content (e.g., amount) of from about 5 mol % to about 20 mol %, K₂O in a content (e.g., amount) of from about 5 mol % to about 20 mol %, and RO in a content (e.g., amount) of from 0 mol % to about 15 mol %, based on the total weight of the glass composition. Here, R may include at least one selected from among (e.g., of) Pb, Mg, Ca, Ba, and Sr.

In this specification, a content (e.g., amount) of 0 mol % refers to substantially no content (e.g., amount) of the corresponding component. The fact that a composition “substantially does not contain” a specific component refers to that it is not intentionally included in the raw materials, and/or the like, and includes cases where trace impurities, such as 0.1 mol % or less, may be (e.g., unavoidably) contained. Additionally, in this specification, ‘about’ may refer to a numerical range of +10% to −10% of the corresponding numerical value.

Hereinafter, each component of the glass composition will be described in more detail as follows.

SiO₂ configures the frame of the glass substrate and may serve to increase chemical durability and reduce the occurrence of cracks if (e.g., when) scratches (indentations) occur on the glass surface. SiO₂ may be a network former oxide that forms a network of glass. The glass substrate WD manufactured including SiO₂ may have a reduced thermal expansion coefficient and improved mechanical strength. In order to sufficiently perform the role or function described herein, SiO₂ may be included in an amount of 55 mol % or more. In order to represent sufficient meltability, the SiO₂ content (e.g., amount) in the glass composition may be 70 mol % or less. Depending on embodiments, SiO₂ may be included in an amount of about 60 mol % to about 65 mol %.

Al₂O₃ serves to improve the friability of glass. For example, Al₂O₃ may produce a smaller number of fragments if (e.g., when) the glass breaks. Al₂O₃ may be an intermediate oxide that forms a bond with SiO₂ to form a network structure. In some embodiments, Al₂O₃ may act as an active component that improves ion exchange performance during chemical strengthening and increases surface compressive stress after strengthening.

When the Al₂O₃ content (e.g., amount) is 0 mol % or more, the herein-described functions may be effectively performed. In one or more embodiments, in order to maintain the acid resistance and meltability of glass, the Al₂O₃ content (e.g., amount) may be 10 mol % or less.

Na₂O may form surface compressive stress through ion exchange and improve the meltability of glass. Na₂O may form non-crosslinked oxygen within the SiO₂ network structure by forming an ionic bond with the oxygen of SiO₂, which forms the network structure. An increase in non-crosslinked oxygen may improve the flexibility of the network structure, and the glass substrate WD may have physical properties that can be applied to a foldable display device. Na₂O may perform the role or function described herein if (e.g., when) the Na₂O has a content (e.g., amount) of 5 mol % or more. Additionally, from the viewpoint of acid resistance of the glass substrate WD, the content (e.g., amount) may be 20 mol % or less.

K₂O may improve the bending reliability of the glass substrate WD. K₂O replaces Na with K, which may increase the compressive stress of the glass substrate. Accordingly, K₂O may contribute to implementing a flexible glass substrate WD by improving the folding and bending reliability of the glass substrate. K₂O may perform the function described herein if (e.g., when) the K₂O is contained in an amount of 5 mol % or more. In terms of meltability of the glass substrate WD, K₂O may have a content (e.g., amount) of 20 mol % or less.

RO may reduce the Young's modulus of a glass substrate. In the RO, R may include at least one selected from among (e.g., of) Pb, Mg, Ca, Ba, and Sr. The glass composition according to one or more embodiments may include at least one selected from among (e.g., of) PbO, MgO, CaO, BaO, and SrO. RO may be included in an amount of about 0 mol % to about 15 mol % based on the total glass composition content (e.g., amount). When RO is included in the content (e.g., amount) described herein, the glass substrate WD manufactured with the glass composition according to one or more embodiments may have a relatively low Young's modulus. A glass substrate according to one or more embodiments may have a Young's modulus of about 45 Gpa to about 70 Gpa. In one or more embodiments, the glass substrate WD according to one or more embodiments may have a Young's modulus of about 60 Gpa to about 70 Gpa. In one or more embodiments, the glass substrate WD according to one or more embodiments may have a Young's modulus of about 60 Gpa to about 65 Gpa. When the glass substrate WD with a relatively low Young's modulus is used in a foldable display device, the occurrence of crease (creasing) due to repeated folding may be prevented or reduced, thereby providing a display device with improved quality.

The glass composition according to one or more embodiments may further include Li₂O. Similar to the herein-described Na₂O, Li₂O may form surface compressive stress of the glass substrate WD through ion exchange and improve the meltability of glass. Li₂O may form non-crosslinked oxygen within the SiO₂ network structure by forming an ionic bond with the oxygen of SiO₂, which forms the network structure. An increase in non-crosslinked oxygen can improve the flexibility and impact absorption function of the network structure, and the glass substrate WD may have physical properties that can be applied to a foldable display device. Li₂O contained in an amount of 10 mol % or more may perform the roles or functions described herein. Additionally, from the viewpoint of heat resistance of the glass substrate WD, the content (e.g., amount) may be 25 mol % or less.

The glass composition having the above-described composition may be molded into a plate glass shape by one or more suitable methods. Once molded into a plate glass shape, the glass composition may be further processed to be manufactured into the glass substrate WD applicable to the display device 10. However, the present disclosure is not limited thereto, and the glass composition may not be formed into a plate glass shape but may be directly molded into the glass substrate WD applicable to a product without an additional molding process.

According to one or more embodiments, the glass substrate WD manufactured from the glass composition described herein may have a thickness in the range of 30 μm to 60 μm and satisfy the following physical properties.

A thermal expansion coefficient (10⁻⁷K⁻¹) of the glass substrate may be about 90*10⁻⁷ per degree Kelvin (/K) to about 200*10⁻⁷/K. In one or more embodiments, the thermal expansion coefficient (10⁻⁷K⁻¹) of the glass substrate according to one or more embodiments may be about 130*10⁻⁷/K to about 200*10⁻⁷/K.

A glass transition temperature T_{g} of the glass substrate may be about 380 degrees centigrade (° C.) to about 500° C. In one or more embodiments, the glass transition temperature T_{g} of the glass substrate according to one or more embodiments may be about 380° C. to about 460° C.

The density of the glass substrate WD according to one or more embodiments may be about 2.7 gram per cubic centimeter (g/cm³) to about 3.2 g/cm³.

The elasticity coefficient (Young's modulus) of the glass substrate WD according to one or more embodiments may be about 45 gigapascal (GPa) to about 70 GPa. In one or more embodiments, the elasticity coefficient (Young's modulus) of the glass substrate WD according to one or more embodiments may be about 60 GPa to about 70 GPa. The elasticity coefficient (Young's modulus) of the glass substrate WD according to one or more embodiments may be about 60 GPa to about 65 GPa.

A Poisson ratio of the glass substrate WD according to one or more embodiments may be about 0.25 to about 0.28. In one or more embodiments, the Poisson ratio of the glass substrate WD according to one or more embodiments may be about 0.27 to about 0.28. The hardness of the glass substrate WD according to one or more embodiments may be about 4.50 GPa to about 5.50 GPa. A fracture toughness of the glass substrate WD according to one or more embodiments may be about 0.6 megapascal·square root meter (MPa*m^{0.5}) to about 1.0 MPa*m^{0.5}. A brittleness of the glass substrate WD according to one or more embodiments may be about 6.0 inverse square root micrometer (μm^{-0.5}) to about 11.0 μm^{-0.5}.

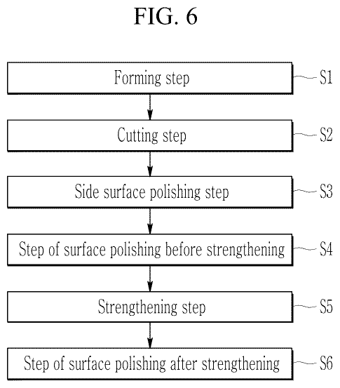

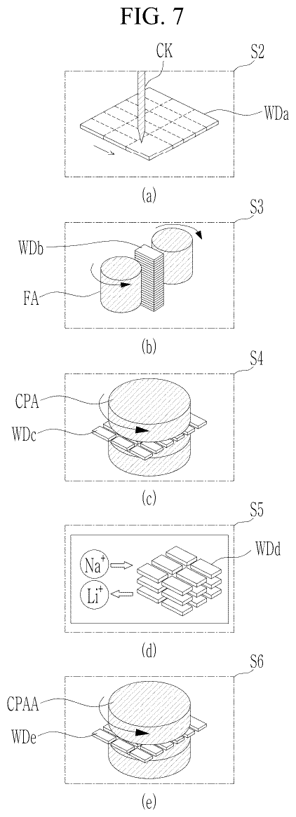

Hereinafter, a process in which the glass composition is molded into a plate glass shape and processed into the glass substrate WD will be described with reference to FIGS. 6 and 7. FIG. 6 is a step-by-step (e.g., act-by-act or task-by-task) flowchart of the manufacturing process of a glass substrate according to one or more embodiments, and FIG. 7 is a schematic view schematically showing from a cutting step (e.g., act or task) to a step (e.g., act or task) of surface polishing after strengthening of FIG. 6.

Referring to FIGS. 6 and 7, a manufacturing method of the glass substrate WD may include a forming step (e.g., act or task) (S1), a cutting step (e.g., act or task) (S2), a side surface polishing step (e.g., act or task) (S3), a step (e.g., act or task) of surface polishing before strengthening (S4), a strengthening step (e.g., act or task) (S5), and a step (e.g., act or task) of surface polishing after strengthening (S6).

The forming step (e.g., act or task) (S1) may include preparing a glass composition and molding the glass composition. The glass composition may have the composition and components as described herein. A detailed description thereof will not be provided.

The glass composition may be formed into a plate glass shape using a float process, a fusion draw process, a slot draw process, and/or the like.

Glass formed into a plate glass shape may be cut through the cutting step (e.g., act or task) (S2) (see (a) of FIG. 7). Glass formed into a flat plate shape (e.g., in a form of plates) may have a different size than that applied to the final glass substrate. For example, glass forming may be performed with a mother substrate Wda including a plurality of glass products in a large-area substrate, which may be cut to manufacture a plurality of glass substrates. Cutting of the mother substrate Wda may be performed using a cutting knife CK, a cutting wheel, a laser, and/or the like.

The cutting step (e.g., act or task) (S2) of glass may be performed before the strengthening step (e.g., act or task) (S5) of the glass. When the mother substrate Wda is strengthened at once and then cut to the final glass substrate size, the cut surface (e.g., the side surface of the glass substrate) may not be strengthened.

A polishing step (e.g., act or task) may be performed between the cutting step (e.g., act or task) (S2) and the strengthening step (e.g., act or task) (S5). The polishing step (e.g., act or task) may include the side surface polishing step (e.g., act or task) (S3) and the step (e.g., act or task) of surface polishing before strengthening (S4). In one or more embodiments, the side surface polishing step (e.g., act or task) (S3) is performed first, followed by the step (e.g., act or task) of surface polishing before strengthening (S4), but this order may be reversed.

The side surface polishing step (e.g., act or task) (S3) is a step (e.g., act or task) of polishing the side surface of the cut glass WDb (see (b) of FIG. 7). In the side surface polishing step (e.g., act or task) (S3), the side surface of the cut glass WDb is polished to have a smooth surface. Additionally, each side surface of the cut glass WDb may have a substantially uniform surface through the side surface polishing step (e.g., act or task) (S3). By polishing each side surface through the side polishing step (e.g., act or task) (S3), each side surface may have substantially uniform surface roughness. Furthermore, if there are small cracks on the side surface, the cracks may be removed through the side surface polishing step (e.g., act or task) (S3).

The side surface polishing step (e.g., act or task) (S3) may be performed concurrently (e.g., simultaneously) on a plurality of cut glasses WDb. For example, in a state where the plurality of cut glasses WDb are stacked, the stacked glasses WDb may be polished concurrently (e.g., simultaneously).

The side surface polishing step (e.g., act or task) (S3) may be performed using a mechanical polishing method or a chemical mechanical polishing method using a polishing device (FA). In one or more embodiments, two opposite to (e.g., facing) side surfaces of the cut glasses WDb may be polished concurrently (e.g., simultaneously), and then the other two opposite to (e.g., facing) side surfaces may be polished concurrently (e.g., simultaneously), but the present disclosure is not limited thereto.

The surface of the cut glass WDc may become substantially uniform in the step (e.g., act or task) of surface polishing before strengthening (S4) (see I of FIG. 7). The step (e.g., act or task) of surface polishing before strengthening (S4) may be performed one by one for each cut glass WDc, but if a chemical mechanical polishing device CPA is sufficiently large compared to the cut glass WDc, a plurality of glasses WDc may be arranged horizontally and then the plurality of glasses WDc may be concurrently (e.g., simultaneously) surface-polished.

The step (e.g., act or task) of surface polishing before strengthening (S4) may be performed using the chemical mechanical polishing device CPA. The chemical mechanical polishing device CPA polishes the first and second surfaces of cut glass WDc. The first surface and the second surface may be polished concurrently (e.g., simultaneously), or one surface may be polished first and then the other surface may be polished.

After the step (e.g., act or task) of surface polishing before strengthening (S4), the strengthening step (e.g., act or task) (S5) may be performed (see (d) of FIG. 7). The strengthening step (e.g., act or task) (S5) may proceed with chemical strengthening and/or thermal strengthening. In the case of glass WDd having a thin thickness of 2 mm or less, and even about 0.75 mm or less, a chemical strengthening method may be appropriately or suitably applied to precisely control the stress profile.

The Young's modulus of the glass substrate according to one or more embodiments may be about 50 GPa to about 70 GPa, and the glass substrate that satisfies the range may use the chemical strengthening method. If the glass substrate has a Young's modulus lower than the herein-described Young's modulus, even if a chemical strengthening process is performed, the binding energy within the glass substrate is high and expansion is difficult, so appropriate or suitable chemical strengthening may not be performed.

After The strengthening step (e.g., act or task) (S5), the step (e.g., act or task) of surface polishing after strengthening (S6) may optionally be further performed (see I of FIG. 7). The step (e.g., act or task) of surface polishing after strengthening (S6) may serve to remove micro cracks on the surface of a tempered glass Wde and control compressive stress on the first and second surfaces of the tempered glass Wde.

The step (e.g., act or task) of surface polishing after strengthening (S6) may be performed using a chemical mechanical polishing method. A chemical mechanical polishing device CPAA uses a polishing slurry to polish the first and second surfaces of the tempered glass Wde. The polishing thickness of the first and second surfaces may be the same, but may also be different.

Although not shown in the drawing, a shape processing process may be further performed if necessary after the step (e.g., act or task) of surface polishing after strengthening (S6). For example, a three-dimensional machining process may be performed after the step (e.g., act or task) of surface polishing after strengthening (S6) is completed.

The glass substrate manufactured through the herein-described process may include a component ratio similar to that of the herein-described glass composition. For example, the glass substrate WD may include may include SiO₂ in a content (e.g., amount) of from about 55 mol % to about 70 mol %, Al₂O₃ in a content (e.g., amount) of from 0 mol % to about 10 mol %, Na₂O in a content (e.g., amount) of from about 5 mol % to about 20 mol %, K₂O in a content (e.g., amount) of from about 5 mol % to about 20 mol %, and BaO in a content (e.g., amount) of from 0 mol % to about 15 mol %.

In one or more embodiments, the display device may be a component of and/or applied to electronic devices such as smartphones, televisions, monitors, tablets, electric vehicles, mobile phones, tablet personal computers (PC), mobile communication terminals, electronic notebooks, electronic books, portable multimedia players (PMP), navigation devices, ultra-mobile personal computers (UMPC), laptop computers, billboards, Internet of Things (IOT) devices, smartwatches, watch phones, or head-mounted displays (HMD). For example, the display device DD may be applied to a display unit of a television, a laptop computer, a monitor, a billboard, or the Internet of Things (IOT). Alternatively, in one or more embodiments, the display device DD may be applied to a smartwatch, a watch phone, and/or a head-mounted display device (HMD) for implementing virtual reality and/or augmented reality.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or +30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

### EXAMPLES

More specific details of the preceding embodiments are described through the examples that follow herein. The composition according to each example is shown in Table 1. In some embodiments, the physical properties for each example were measured and shown in Table 2.

Each of Examples 1 to 12 according to Table 1 was prepared in the following method.

First, glass blocks were formed using a 10% PtRh crucible, weighed in 500 g increments per composition, heated to 1500° C. at a rate of 10 degrees Kelvin per minute (K/min), held for 2.0 hours (h), and then quenched in a carbon mold at 600° C.

To remove residual stress in the manufactured glass block, the glass blocks were maintained at 500° C. for 3.0 h and then furnace cooled to room temperature at a rate of 1 K/min. Each glass block was sliced to 270 micrometer (μm) using a diamond wire saw, and then polished on both (e.g., simultaneously) side surfaces to 50 μm. The glass substrate according to each example was manufactured to have a thickness of 50 μm.

TABLE 1

| Experimental | | K₂O | Na₂O | BaO |
|---|---|---|---|---|
| Example ID | SiO₂ | (K₂CO₃) | (Na₂CO₃) | (BaCO₃) |
| 1 | 60 | 20 | 20 | 0 |
| 2 | 60 | 15 | 20 | 5 |
| 3 | 60 | 10 | 20 | 10 |
| 4 | 65 | 10 | 15 | 10 |
| 5 | 60 | 5 | 20 | 15 |
| 6 | 60 | 15 | 15 | 10 |
| 7 | 60 | 20 | 10 | 10 |
| 8 | 60 | 10 | 15 | 15 |
| 9 | 65 | 5 | 15 | 15 |
| 10 | 65 | 15 | 10 | 10 |
| 11 | 65 | 20 | 5 | 10 |
| 12 | 65 | 10 | 10 | 15 |

The physical properties listed in Table 2 were measured as follows. The coefficient of thermal expansion (CTE) of the glass substrate was analyzed using Thermos mechanical analyzer (TMA) equipment. For each example, a 10 millimeter (mm)×10 mm×13 mm (e.g., 1300 cubic millimeter (mm3)) specimen was manufactured and heated up to the glass transition temperature range at a rate of 10 K/min to determine the coefficient of thermal expansion of the glass substrate for each example.

The glass transition temperature T_{g} was analyzed using differential thermal analysis (DTA) equipment. 5 g of each example was prepared and the transition temperature was confirmed while heating at a rate of 10 K/min to the glass transition temperature range.

Density d was analyzed using electronic densimeter equipment. 10 g was prepared for each example, and the specific gravity was confirmed by checking the mass of the specimen, the mass of the specimen immersed in the liquid, and the mass of the weight and wire, and then the final density was calculated. The standard density of water was set at 25° C.

Young's Modulus E and Poisson ratio v were analyzed using an elastic modulus tester. For each example, a specimen with a size of 10 mm×20 mm×3 mm (e.g., 600 mm³) was produced, and the Young's modulus and Poisson ratio were confirmed by checking the stress and strain of the specimen.

Hardness H_{V} and fracture toughness K_{IC} of the glass were calculated by applying a load of 4.9 newton (N) for 30 seconds with a Vickers hardness tester using a 19 μm diamond tip, using Equations (1) and (2).

$${H}_{V} = 1.854 \cdot \frac{F}{{a}^{2}} \qquad Equation ( 1 )$$

Here, H_{V} represents Vickers hardness, F represents load, and a represents indentation length.

$$\frac{{K}_{IC} \cdot ϕ}{{H}_{V} \cdot {a}^{\frac{1}{2}}} = 0.15 \cdot K \cdot {( \frac{c}{a} )}^{- \frac{3}{2}} \qquad Equation ( 2 )$$

Here, K_{IC} represents fracture toughness, Φ represents confinement index (Φ≈3), H_{V} represents Vickers hardness, K represents a constant (=3.2), c represents crack length, and a represents indentation length.

Brittleness (B) of glass was calculated using Equation (3) by applying a load of 4.9 N for 30 seconds using the Vickers hardness tester.

$$B = γ {P}^{- 1 / 4} {\frac{C}{a}}^{3 / 2} \qquad Equation ( 3 )$$

Here, B is brittleness, γ is a constant (2.39 N^{1/4}/um^{1/2}), P is indentation load, a is indentation length, and C is crack length.

TABLE 2

| | Thermal | Glass | | | | | | | |
|---|---|---|---|---|---|---|---|---|---|
| | expansion | transition | | Young's | | | | Fracture | |
| Ex. | coefficient | temperature | Density | modulus | Poisson | Packing | Hardness | toughness | Brittleness |
| No. | (10⁻⁷ K⁻¹) | (° C.) | (g/cm³) | (GPa) | ratio | density | (Hv) | (MPa*m^{0.5}) | (μm^{-0.5}) |
| 1 | — | — | — | — | — | — | — | — | — |
| 2 | 189.2 | 396 | 2.720 | 63 | 0.271 | 0.547 | 466 | 0.78 | 7.68 |
| 3 | 172.7 | 380 | 2.899 | 66 | 0.281 | 0.548 | 506 | 0.910 | 6.65 |
| 4 | 179.7 | 397 | 2.864 | 64 | 0.273 | 0.547 | 506 | 0.840 | 7.18 |
| 5 | 164.0 | 419 | 3.087 | 68 | 0.273 | 0.549 | 507 | 0.720 | 8.32 |
| 6 | 197.5 | 396 | 2.924 | 64 | 0.273 | 0.555 | 498 | 0.610 | 9.85 |
| 7 | 184.9 | 411 | 2.874 | 63 | 0.273 | 0.549 | 468 | 0.590 | 10.17 |
| 8 | 168.9 | 422 | 3.055 | 67 | 0.273 | 0.547 | 509 | 0.720 | 8.39 |
| 9 | 138.9 | 461 | 3.107 | 68 | 0.273 | 0.559 | 516 | 0.980 | 6.12 |
| 10 | 154.6 | 422 | 2.847 | 63 | 0.273 | 0.547 | 493 | 0.910 | 6.62 |
| 11 | 149.3 | 458 | 3.068 | 64 | 0.275 | 0.592 | 474 | 0.820 | 7.35 |
| 12 | 174.4 | 451 | 2.857 | 59 | 0.275 | 0.517 | 517 | 0.700 | 8.62 |

According to Table 2, it can be seen that the glass substrate manufactured from the glass composition according to one or more embodiments may have: i) the thermal expansion coefficient (10⁻⁷ K⁻¹) of about 130*10⁻⁷/K to about 200*10⁻⁷/K; ii) the glass transition temperature T_{g} of about 380 degrees (C.) to about 461 degrees (C.); iii) the density of about 2.7 g/cm³ to about 3.2 g/cm³; iv) the elasticity coefficient (Young's modulus) of about 59 GPa to about 70 GPa; v) the Poisson ratio of about 0.27 to about 0.28; vi) the hardness of about 4.50 GPa to about 5.50 GPa; vii) the fracture toughness of about 0.6 MPam^{0.5} to about 1.0 MPa*m^{0.5}; and viii) the brittleness of about 6.0 μm^{-0.5} about 11.0 μm^{-0.5}. The glass substrate manufactured from the glass composition according to one or more embodiments may have a relatively low Young's modulus, and when used in a foldable display device, the occurrence of crease (creasing) due to repeated folding may be prevented or reduced, thereby providing a display device with improved quality. In other words, according to Table 2, it can be seen that the glass substrate manufactured from the glass composition according to one or more embodiments may have various desirable or suitable properties. For example, it may have a specific range of desirable or suitable thermal expansion coefficients, glass transition temperatures, densities, elasticity coefficients (Young's modulus), Poisson ratios, hardness levels, fracture toughness, and/or brittleness. The glass substrate may have a relatively low Young's modulus, which can help prevent or reduce creasing in foldable display devices, thereby improving the quality of the display device.

The display device, the electronic device, a device of manufacturing thereof, and/or any other relevant devices or components according to embodiments of the present disclosure described herein may be implemented utilizing any suitable hardware, firmware (e.g., an application-specific integrated circuit), software, or a combination of software, firmware, and hardware. For example, the one or more suitable components of the display and/or electronic device may be formed on one integrated circuit (IC) chip or on separate IC chips. Further, the one or more suitable components of the display and/or electronic device may be implemented on a flexible printed circuit film, a tape carrier package (TCP), a printed circuit board (PCB), or formed on one substrate. Further, the one or more suitable components of the display and/or electronic device may be a process or thread, running on one or more processors, in one or more computing devices, executing computer program instructions and interacting with other system components for performing the one or more suitable functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

In the context of the present application and unless otherwise defined, the terms “use,” “using,” and “used” may be considered synonymous with the terms “utilize,” “utilizing,” and “utilized,” respectively.

A person of ordinary skill in the art, in view of the present disclosure in its entirety, would appreciate that each suitable feature of the one or more suitable embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied.

It should be understood that embodiments described herein should be considered in a descriptive sense only and not for purposes of limitation. Descriptions of features or aspects within each embodiment should typically be considered as available for other similar features or aspects in one or more embodiments. While one or more embodiments have been described with reference to the drawings, it will be understood by those of ordinary skill in the art that one or more suitable changes in form and details may be made therein without departing from the spirit and scope as defined by the following claims and equivalents thereof.

While one or more embodiments of the present disclosure have been described in more detail, it is to be understood that the disclosure is not limited to the disclosed embodiments, but on the contrary, is intended to cover one or more suitable modifications and equivalent arrangements included within the spirit and scope of the appended claims and equivalents thereof.

### REFERENCE NUMERALS

10: Display device
WD: Glass substrate
AD: Adhesive layer
DP: Display panel

What is claimed is:

1. A glass composition, comprising:
about 55 mol % to about 70 mol % of SiO₂;
0 mol % to about 10 mol % of Al₂O₃;
about 5 mol % to about 20 mol % of Na₂O;
about 5 mol % to about 20 mol % of K₂O; and
0 mol % to about 15 mol % of RO,
wherein R comprises at least one selected from among Pb, Mg, Ca, Ba, and Sr.

2. The glass composition of claim 1, comprising
about 60 mol % to about 65 mol % of SiO₂.

3. The glass composition of claim 1, further comprising
Li₂O.

4. A glass substrate made from the glass composition according to claim 1.

5. The glass substrate of claim 4, wherein
a thickness of the glass substrate is about 30 micrometer (μm) to about 60 μm.

6. The glass substrate of claim 4, wherein
a thermal expansion coefficient (10⁻⁷K⁻¹) of the glass substrate is about 90*10⁻⁷ per degree Kelvin (/K) to about 200*10⁻⁷/K.

7. The glass substrate of claim 6, wherein
the thermal expansion coefficient (10⁻⁷K⁻¹) of the glass substrate is about 130*10⁻⁷/K to about 200*10⁻⁷/K.

8. The glass substrate of claim 4, wherein
a glass transition temperature T_{g} of the glass substrate is about 380° C. to 500 degrees °C.

9. The glass substrate of claim 4, wherein
a density of the glass substrate is about 2.7 gram per cubic centimeter (g/cm³) to about 3.2 g/cm³.

10. The glass substrate of claim 4, wherein
a Young's modulus of the glass substrate is about 45 gigapascal (GPa) to about 70 GPa.

11. The glass substrate of claim 10, wherein
the Young's modulus of the glass substrate is about 60 GPa to about 70 GPa.

12. The glass substrate of claim 4, wherein
a Poisson ratio of the glass substrate is about 0.25 to about 0.28.

13. The glass substrate of claim 4, wherein
a hardness of the glass substrate is about 4.50 GPa to about 5.50 GPa.

14. The glass substrate of claim 4, wherein
a fracture toughness of the glass substrate is about 0.6 megapascal.square root meter (MPa*m^{0.5}) to about 1.0 MPa*m^{0.5}.

15. The glass substrate of claim 4, wherein
a brittleness of the glass substrate is about 6.0 inverse square root micrometer (um^{-0.5}) to about 11.0 μm^{-0.5}.

16. A display device, comprising:
a display panel comprising a plurality of pixels; and
a glass substrate on the display panel,
wherein a composition of the glass substrate comprises:
about 55 mol % to about 70 mol % of SiO₂;
0 mol % to about 10 mol % of Al₂O₃;
about 5 mol % to about 20 mol % of Na₂O;
about 5 mol % to about 20 mol % of K₂O; and
0 mol % to about 15 mol % of RO, and
wherein R comprises at least one selected from among Pb, Mg, Ca, Ba, and Sr.

17. The display device of claim 16, wherein
a thickness of the glass substrate is about 30 μm to about 60 μm.

18. The display device of claim 16, wherein
a Young's modulus of the glass substrate is about 60 GPa to about 70 GPa.

19. An electronic device comprising a display device comprising:
a display panel comprising a plurality of pixels; and
a glass substrate on the display panel,
wherein a composition of the glass substrate comprises:
about 55 mol % to about 70 mol % of SiO₂;
0 mol % to about 10 mol % of Al₂O₃;
about 5 mol % to about 20 mol % of Na₂O;
about 5 mol % to about 20 mol % of K₂O; and
0 mol % to about 15 mol % of RO, and
wherein R comprises at least one selected from among Pb, Mg, Ca, Ba, and Sr.

20. The electronic device of claim 19, wherein the electronic device is a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (loT) device, a smartwatch, a watch phone, or a head-mounted display (HMD).
